(19) United States
(12) Patent Application Publication
(10) Pub. No.: US 2012/0094213 A1
(43) Pub. Date: Apr. 19, 2012

(54) SOLID OXIDE ELECTROLYTE MEMBRANE, METHOD OF MANUFACTURING THE SAME AND FUEL CELL INCLUDING THE SOLID OXIDE ELECTROLYTE MEMBRANE

(75) Inventors: Jin-su HA, Seoul (KR); Sang-kyun KANG, Seoul (KR); Pil-won HEO, Yongin-si (KR); Yoon-ho LEE, Seoul (KR); Suk-won CHA, Seoul (KR); Ik-whang CHANG, Daegu (KR); Tae-young KIM, Seoul (KR); Un-jeong KIM, Osan-si (KR)

(73) Assignee: Samsung Electronics Co., Ltd., Suwon-si (KR)

(21) Appl. No.: 13/227,008

(22) Filed: Sep. 7, 2011

(30) Foreign Application Priority Data
Oct. 19, 2010 (KR) 10-2010-0101879

(51) Int. Cl. H01M 8/10; B05D 5/00; C23C 16/44; C25D 15/00

(52) U.S. Cl. 429/495; 205/109; 427/58

(57) ABSTRACT

A solid oxide electrolyte membrane including a solid oxide electrolyte layer; and an insulating layer formed as a conformal layer on a single surface or two opposite surfaces of the solid oxide electrolyte layer and including nano-grains having a average crystal grain size of 30 nm or less, a method of manufacturing the solid oxide electrolyte membrane, and a fuel cell including the solid oxide electrolyte membrane.

### CROSS-REFERENCE TO RELATED APPLICATIONS

This application claims the benefit of Korean Patent Application No. 10-2010-0101879, filed on Oct. 19, 2010, in the Korean Intellectual Property Office, the disclosure of which is incorporated herein in its entirety by reference.

### BACKGROUND OF THE INVENTION

1. Field

The present disclosure relates to solid oxide electrolyte membranes, methods of manufacturing the same, and fuel cells including the solid oxide electrolyte membrane. Throughout the specification and claims, all expressed temperatures are in Centigrade, unless otherwise indicated

2. Description of the Related Art

A type of fuel cell has a structure in which an electrolyte is disposed between two electrodes, an anode and a cathode, each formed of an electrochemical catalyst comprising a porous metal, porous ceramic or carbon. This type of fuel cell is referred to as a single cell. In the anode (the fuel electrode) and cathode (the air electrode), hydrogen gases or other fuels and oxygen are supplied from an external source, respectively. The hydrogen gases or other fuels and oxygen that reach the reaction zone through the pores of the electrodes, are adsorbed onto the catalyst in the electrodes and are dissociated to become ions and electrons. The ions move through the electrolyte to react at the other electrode to form water. During the electrochemical reactions, electrons are generated at the anode to produce electricity.

A solid oxide fuel cell (SOFC) is a kind of a high-temperature type fuel cell that uses a ceramic electrolyte, and is a high-efficiency environmentally friendly electrochemical power generation technology for converting the chemical energy of a fuel gas into electrical energy.

Since a typical SOFC is capable of using various fuels by virtue of its high electrical efficiency and low requirements for purity of the fuel gas, the typical SOFC has become known as a fuel cell that holds promise as a decentralized power supply. However, a SOFC operates at a high temperature of 800° to 1,000° C. Since the SOFC requires expensive peripheral materials that remain durable in high-temperature environments, and cannot be rapidly powered on and off, it is difficult to use the SOFC in various power generators such as portable power sources, power sources for vehicles and the like. Thus, research has been actively conducted to develop new electrolytes for driving a SOFC at a low temperature and thinned electrolyte membranes for lowering the operating temperature of the SOFC.

Examples of new electrolytes include an oxygen-ion conductive electrolyte such as a CeO₂-based electrolyte, a LaSrMnO₃-based electrolyte and the like, and hydrogen-ion conductive electrolytes such as a BaCeO₃-based electrolyte, a BaZrO₃-based electrolyte, and the like. However, even where new electrolytes are developed, it is difficult to lower the operating temperature to 400° C. or less due to the ion conductivity characteristics of inorganic electrolytes.

Typically, a thin electrolyte membrane is obtained by using a bulk process of sintering powders. However, recently, a thin electrolyte membrane has been produced by using a deposition method, such as physical vapor deposition (PVD), chemical vapor deposition (CVD) and the like; tape casting using slurry; spray pyrolysis; or the like. However, long periods of time are required to densely deposit an electrolyte by using CVD methods. In addition, there is a limit to obtaining an appropriate thickness of a membrane by using PVD, tape casting, spray pyrolysis techniques or the like. That is, a membrane having a thickness of about 1 μm may be formed by using PVD methods. In addition, a membrane having a thickness of several tens of μm or more may be formed by using tape casting or spray tape casting techniques. Thus, in order to form a dense membrane by using the above-described methods, process times are increased, and the thicknesses of the electrolyte membrane are increased. Moreover, the performances of the fuel cells utilizing these membrane electrolytes may not be high, or the fuel cell may not operate at a temperature of 400° C. or less.

In order to overcome these problems, the thickness of electrolyte membranes must be minimized. If the electrolyte membrane is not densely formed, however, short circuits may occur between two electrodes due to defects in the electrolyte.

### SUMMARY OF THE INVENTION

One aspect of the invention relates to solid oxide electrolyte membranes including insulating layers that fill pin holes formed in an electrolyte layer to thus prevent short circuits from occurring where two electrodes are electrically connected and the electrolyte layer is thinned in order to reduce the operating temperature.

Other aspects of the invention concern fuel cells including the above described solid oxide electrolyte membranes, which can be driven at low temperatures.

Additional aspects of the invention comprise methods of manufacturing the solid oxide electrolyte membranes.

Additional aspects and/or advantages of the invention will be set forth in part in the description which follows and, in part, will be obvious from the description, or may be learned through practice of the invention by those skilled in the art.

According to an aspect of the invention, the solid oxide electrolyte membrane comprises a solid oxide electrolyte layer; and an insulating layer(s) formed as a conformal layer on a single surface or two opposing surfaces of the solid oxide electrolyte layer and further, optionally, comprising nano-grains having an average crystal grain size of 30 nm or less.

The solid oxide electrolyte layer may include at least one member selected from the group consisting of an oxygen ion conductive solid oxide, a hydrogen ion conductive solid oxide, and an oxygen ion and hydrogen ion mixed conductive solid oxide.

The oxygen ion conductive solid oxide may include at least one member selected from the group consisting of zirconia doped with yttrium (Y) or scandium (Sc); ceria doped with at least one of gadolinium, samarium, lanthanium, ytterbium and neodymium; and lanthanum gallate doped with strontium or magnesium.

The hydrogen ion conductive solid oxide may include at least one member selected from a parent perovskite group consisting essentially of barium zirconate, barium cerate, strontium cerate and strontium zirconate, which are each doped with a trivalent element.

The oxygen ion and hydrogen ion mixed conductive solid oxide may include at least one member selected from the group consisting of BaZrO₃, BaCeO₃, SrZrO₃ and SrCeO₃ which is doped with a trivalent element; and Ba₂In₂O₅ doped with at least one positive ion of at least one of vanadium, niobium, tantalum, molybdenum and tungsten.

The insulating layer may include at least one member selected from the group consisting of an oxygen ion conductive solid oxide, a hydrogen ion conductive solid oxide, and an oxygen ion and hydrogen ion mixed conductive solid oxide.

The oxygen ion conductive solid oxide may include at least one member selected from the group consisting of zirconia that may optionally be doped with yttrium (Y) or scandium (Sc); ceria which may optionally be doped with at least one of gadolinium, samarium, lanthanium, ytterbium and neodymium; and lanthanum gallate that may optionally be doped with strontium or magnesium.

The hydrogen ion conductive solid oxide may include at least one member selected from a parent perovskite group consisting essentially of barium zirconate, barium cerate, strontium cerate and strontium zirconate, each of which may optionally be doped with a trivalent element.

The oxygen ion and hydrogen ion mixed conductive solid oxide may include at least one member selected from the group consisting of BaZrO₃, BaCeO₃, SrZrO₃ or SrCeO₃, each of which may optionally be doped with a trivalent element; and Ba₂In₂O₅ that may optionally be doped with at least one positive ion of vanadium, niobium, tantalum, molybdenum and tungsten.

The insulating layer may also include at least one member selected from the group consisting of aluminum oxide, aluminosilicates and titanium oxide.

The insulating layer may also include nano-grains having an average crystal grain size of 30 nm or less.

According to another aspect of the invention, there is provided a method of manufacturing a solid oxide electrolyte membrane comprising forming an insulating layer as a conformal layer on at least one solid oxide electrolyte layer, wherein the insulating layer may include nano-grains having an average crystal grain size of 30 nm or less.

The forming of the insulating layer may be performed by a chemical vapor deposition (CVD) method, a plating method, a molecular-beam epitaxy method, a vacuum deposition method, an atomic layer deposition (ALD) method or the like.

According to another aspect of the invention, a fuel cell is provided which includes the above-described solid oxide electrolyte membranes.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a cross-sectional view of a fuel cell according to an embodiment of the invention;

FIG. 2 is a cross-sectional view of a fuel cell according to another embodiment of the invention;

FIG. 3 is a cross-sectional view of a fuel cell according to another embodiment of the invention;

FIG. 4 is a graph illustrating results of an electrochemical impedance spectroscopy (EIS) test of fuel cells of Examples 1 through 3; and

FIG. 5 is a graph illustrating results of an EIS test of fuel cells of Comparative Examples 1 through 3.

### DETAILED DESCRIPTION OF THE INVENTION

Reference will now be made in detail to the present embodiments of the invention, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described below in order to explain the present invention by referring to the figures.

Hereinafter, a solid oxide electrolyte membrane, a method of manufacturing the same and a fuel cell including the solid oxide electrolyte membrane will be described with regard to exemplary embodiments of the invention and with reference to the attached drawings.

According to an embodiment of the invention, a solid oxide electrolyte membrane is provided which comprises a solid oxide electrolyte layer; and an insulating layer formed as a conformal layer on a single surface or two opposing surfaces of the solid oxide electrolyte layer and wherein either or both of the solid oxide electrolyte membrane and insulating layer further comprises nano-grains having an average crystal grain size of 30 nm or less.

The solid oxide electrolyte layer may comprise at least one member selected from the group consisting of an oxygen ion conductive solid oxide, a hydrogen ion conductive solid oxide, and an oxygen ion and hydrogen ion mixed conductive solid oxide.

In further detail, the oxygen ion conductive solid oxide may comprise, but is not limited to at least one member selected from the group consisting of zirconia doped with yttrium (Y) or scandium (Sc); ceria doped with at least one of gadolinium, samarium, lanthanium, ytterbium and neodymium; and lanthanum gallate doped with strontium or magnesium.

The hydrogen ion conductive solid oxide may comprise, but is not limited to at least one member selected from a parent perovskite group consisting of barium zirconate, barium cerate, strontium cerate and strontium zirconate, which are each doped with a trivalent element.

The oxygen ion and hydrogen ion mixed conductive solid oxide may comprise, but is not limited to at least one member selected from the group consisting of BaZrO₃, BaCeO₃, SrZrO₃ or SrCeO₃ which is doped with a trivalent element; and Ba₂In₂O₅ doped with at least one positive ion of at least one of vanadium, niobium, tantalum, molybdenum and tungsten.

The solid oxide electrolyte layer may have a thickness of 10 μm or less. For example, the solid oxide electrolyte layer may have a thickness ranging from about 5 nm to about 2 μm. For example, the solid oxide electrolyte layer may have a thickness ranging from about 50 nm to about 1.5 μm. For example, the solid oxide electrolyte layer may have a thickness ranging from about 100 nm to about 1.2 μm.

The insulating layer is formed as a conformal layer on a single surface or two opposing surfaces of the solid oxide electrolyte layer so as to fill and cover any pin holes formed in the solid oxide electrolyte layer, and thus prevent short circuits from occurring. The short circuits may occur when an anode and a cathode, each disposed on the two opposing surfaces of the solid oxide electrolyte layer, are electrically connected to each other.

The insulating layer may include nano-grains having an average crystal grain size of 30 nm or less in order to reduce the density of any pin holes by effectively filling same.

The average crystal grain size of the nano-grains of the insulating layer may be, for example, about 10 to about 30 nm, about 10 to about 20 nm, or about 15 to about 20 nm. If the average crystal grain size of the nano-grains of the insulating layer is within the range described above, the insulating layer may be formed as a conformal layer on the solid oxide electrolyte layer so as to effectively fill any pin holes. Thus, although the thickness of the solid oxide electrolyte layer is reduced, pin holes are not likely to be formed thus preventing short circuits from occurring. In addition, when the thickness of the solid oxide electrolyte layer is reduced, since the resistance of the electrolyte is reduced, a fuel cell including the solid oxide electrolyte layer may be driven at a lower temperature.

The insulating layer may include the same materials as those of the solid oxide electrolyte layer, that is, at least one member selected from the group consisting of an oxygen ion conductive solid oxide, a hydrogen ion conductive solid oxide, and an oxygen ion and hydrogen ion mixed conductive solid oxide. The insulating layer may include either the doped or undoped materials included in the solid oxide electrolyte layer. In addition, the insulating layer material may include, but is not limited to, at least one member selected from the group consisting of aluminum oxide, aluminosilicates and titanium oxide.

In further detail, the oxygen ion conductive solid included in the insulating layer may include at least one member selected from the group consisting of zirconia that may optionally be doped with yttrium (Y) or scandium (Sc); ceria that may optionally be doped with at least one of gadolinium, samarium, lanthanium, ytterbium and neodymium; and lanthanum gallate that may optionally be doped with strontium or magnesium.

The hydrogen ion conductive solid oxide included in the insulating layer may include at least one member selected from a parent perovskite group consisting essentially of barium zirconate, barium cerate, strontium cerate and strontium zirconate, each of which may optionally be doped with a trivalent element.

The oxygen ion and hydrogen ion mixed conductive solid oxide included in the insulating layer may include at least one member selected from the group consisting of BaZrO₃, BaCeO₃, SrZrO₃ or SrCeO₃ each of which may optionally be doped with a trivalent element; and Ba₂In₂O₅ that may optionally be doped with at least one positive ion selected from the group consisting of vanadium, niobium, tantalum, molybdenum and tungsten.

The insulating layer is easily deposited since it has appropriate ion conductivity and is inexpensive. Although the material used in the insulating layer has lower ion conductivity that that of the solid oxide electrolyte layer, since the thickness of the insulating layer is smaller than the thickness of the solid oxide electrolyte layer, the insulating layer may not function as an obstacle when ions are transported to electrodes through the solid oxide electrolyte layer, and thus the performance of a fuel cell which includes the solid insulating layer is not reduced.

The solid oxide electrolyte layer may be formed by physical vapor deposition (PVD) such as sputtering and pulsed laser deposition (PLD), which can be performed at low cost, spray pyrolysis, tape casting, or the like. In this case, the solid oxide electrolyte layer has a crystal grain size of several tens of nm to several μm. Since there is a need to thin the solid oxide electrolyte layer in order to reduce the resistance of the solid oxide electrolyte layer to provide a low-temperature type fuel cell, the solid oxide electrolyte layer may be likely to develop defects causing short circuits, such as pin holes formed in the solid oxide electrolyte layer.

The insulating layer may be formed by using any method as long as it is formed as a conformal layer with respect to the solid oxide electrolyte layer surface(s). For example, the method may comprise, but is not limited to a chemical vapor deposition (CVD) method such as, for example, atomic layer deposition (ALD); a plating method; a molecular-beam epitaxy method; a vacuum deposition method or the like.

Since the insulating layer may have a uniform thickness so as to conform to a change in the smoothness of the solid oxide electrolyte layer, when concave portions such as pin holes are formed in the solid oxide electrolyte layer, the conformal insulating layer formed using an ALD method, for example, may be thinly formed to have a uniform thickness along vertical and bottom surfaces of the concave portions. On the other hand, typically, the insulating layer is only formed on the bottom surfaces of the concave portions.

As a result, the insulating layer may completely surround concave or protruding portions of the solid oxide electrolyte layer to thus minimize the density of any pin hole formed in the solid oxide electrolyte layer. In addition, grains included in the insulating layer are controlled to have an average crystal grain size of 30 nm or less to thus prevent short circuits from occurring between the anode and cathode.

The insulating layer may have a thickness of, for example, about 50 nm or less, from about 5 to about 30 nm, or about 20 to about 30 nm. If the thickness of the insulating layer is within this range, the performance of a fuel cell may be prevented from being reduced while, at the same time, minimizing the number of processes required for forming the insulating layer to thus provide a low-temperature type fuel cell.

According to an embodiment of the invention, a fuel cell which includes the above-described solid oxide electrolyte membrane is provided.

The fuel cell includes an anode; a cathode; a solid oxide electrolyte layer disposed between the anode and the cathode; and an insulating layer disposed between the solid oxide electrolyte layer and at least one of the anode and the cathode, wherein the insulating layer is formed as a conformal layer on the solid oxide electrolyte layer(s) and which may include nano-grains having an average crystal grain size of 30 nm or less.

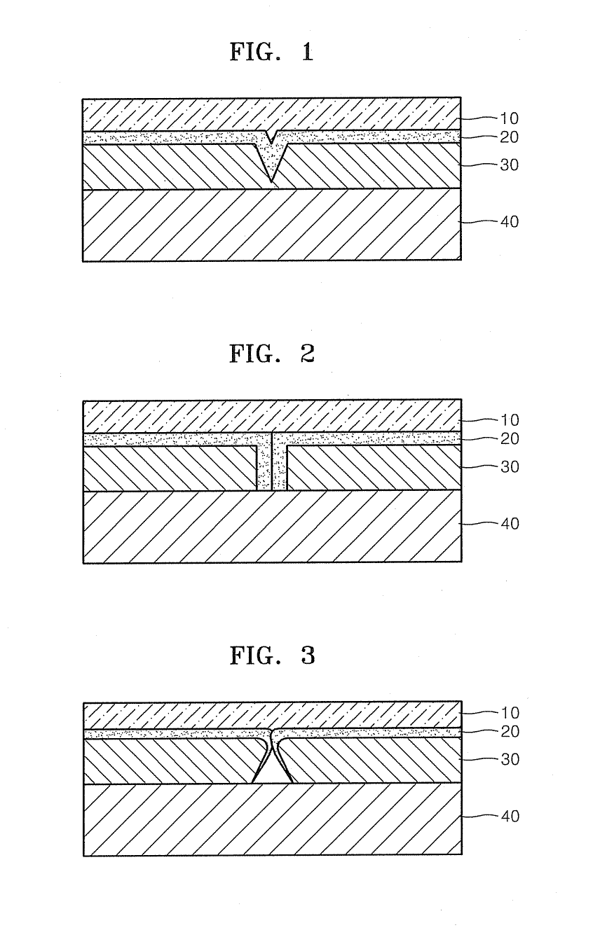

FIGS. 1 through 3 are cross-sectional views of solid oxide fuel cells according to embodiments of the invention.

Referring to FIGS. 1 through 3, a solid oxide fuel cell according to an embodiment of the invention includes an anode 40, a solid oxide electrolyte layer 30, an insulating layer 20 and a cathode 10. A solid oxide fuel cell according to an embodiment of the invention may further include an insulating layer disposed between the anode 40 and an electrolyte layer 30, or may include an insulating layer disposed only between the anode 40 and the electrolyte layer 30.

The anode 40 and the cathode 10 may be each, independently, a porous membrane or a non-porous membrane. The pores of porous anodes 40 or cathodes 10 may be, for example, from about 5 nm to about 500 nm, and may be appropriately adjusted if necessary.

The anode 40 and the cathode 10 may each be an oxygen ion and hydrogen ion permeable membrane. The anode 40 and the cathode 10 may each, independently, include at least one member selected from the group consisting of perovskite doped with at least one of platinum (Pt), nickel (Ni), palladium (Pd), silver (Ag), barium (Ba) and cobalt (Co); zirconia doped with yttrium (Y) or scandium (Sc); ceria doped with at least one of gadolinium, samarium, lanthanium, ytterbium and neodymium; at least one proton conductive metal selected from Pd, a Pd—Ag alloy, RuO₂, HₓWO₃ (0<x≦1) and vanadium (V); zeolite; strontium manganese oxide (LSM) doped with lanthanum or calcium; lanthanum strontium cobalt iron oxide (LSCF); nickel oxide (NiO); and tungsten carbide (WC) or any material that may be used to form an anode or a cathode.

The anode 40 and the cathode 10 may each, independently, have a thickness of 5 mm or less. For example, the anode 40 and the cathode 10 may each, independently, have a thickness ranging from about 5 nm to about 1 μm. For example, the anode 40 and the cathode 10 may each independently have a thickness ranging from about 5 nm to about 500 nm. For example, the anode 40 and the cathode 10 may each, independently, have a thickness ranging from about 5 nm to about 200 nm.

At least one of the anode 40 and the cathode 10 may further include a catalyst. For example, the catalyst may be further disposed on surfaces of each of the anode 40 and the cathode 10. For example, a porous catalyst layer including the catalyst may be disposed on each of the anode 40 and the cathode 10. The catalyst may have particles of the size of a submicron. The catalyst may also have a nano-particle size.

The catalyst may be at least one metal catalyst or alloy catalyst, or at least two metal catalysts or alloy catalysts selected from the group consisting of platinum (Pt), gold (Au), silver (Ag), ruthenium (Ru), nickel (Ni), palladium (Pd), cobalt (Co), titanium (Ti) and vanadium (V). The catalyst may include at least one oxide catalyst selected from La₁₋ₓSrₓMnO₃ (0<x<1). La₁₋ₓSrₓCoO₃ (0<x<1) and La₁₋ₓSrₓCo_{y}Fe_{1-y}O₃ (0<x<1, 0<y<1). For example, the catalyst may include at least one member selected from the group consisting of Pt, Pt—Ru, Pt—Co, Pt—Fe, Pt—Ni, Pt—Ti and Pt—V. Due to the presence of the catalyst, the ionization rate of hydrogen and oxygen may be increased.

The solid oxide electrolyte layer 30 is disposed between the anode 40 and the cathode 10 so as to transport hydrogen ions or oxygen ions between the anode 40 and the cathode 10 and to prevent hydrogen and oxygen from contacting each other. The solid oxide electrolyte layer 30 may simultaneously transport hydrogen ions and oxygen ions.

The solid oxide fuel cell may use, as fuel, at least one member selected from the group consisting of hydrogen, methane, a natural gas, methanol, ethanol, dimethylether and a liquefied hydrocarbon gas.

According to an embodiment of the invention, a method of manufacturing the solid oxide electrolyte membrane is provided which comprises forming an insulating layer as a conformal layer on the solid oxide electrolyte layer(s), wherein the insulating layer may include nano-grains having an average crystal grain size of 30 nm or less.

The insulating layer may be formed by using any method that forms a conformal layer as described above. For example, chemical vapor deposition (CVD) methods, including atomic layer deposition (ALD); a plating method; a molecular-beam epitaxy method or a vacuum deposition method may be used.

The atomic layer deposition method will be described below in detail.

A precursor in a gas state is allowed to flow into a chamber under vacuum, and precursor molecules and a surface of a substrate on which deposition is to be performed are combined by chemisorption. In this case, molecules that are not chemisorbed are physisorbed or are present un-combined. In this case, all molecules other than the precursor molecules that are chemisorbed are removed by purging with inert gas. A reaction material and ligand of the precursor are reacted with each other so as to deposit a desired material on the substrate. ALD reactions are self-limiting reactions. Since the thickness of a membrane may be adjusted in units of atom layers, the membrane may have any predetermined thickness. In addition, since chemisorption between the surface of the substrate and the precursor molecules is used, even if the surface of the substrate is not flat, a membrane may be formed on the surface of the substrate having a uniform thickness.

That is, when ALD is used, an insulating layer having a very small thickness of a unit of an atom may be formed as a conformal layer on the electrolyte. As a result, the insulating layer may have a reduced thickness while effectively filling any defects which cause short circuits, such as pin holes formed in the electrolyte layer, to thus provide a low-temperature type fuel cell.

With regard to ALD for forming the insulating layer, when an electrolyte layer is formed to have a relatively large thickness by using only ALD, a very dense electrolyte layer may be formed. However, ALD requires a long time to perform and costs are high. Accordingly, ALD alone is not appropriate for mass production. However, even if several pin holes are formed, the electrolyte layer may be formed by a physical deposition method such as sputtering, CVD, PVD, ALD, plating, PLD, molecular-beam epitaxy or vacuum deposition at relatively low costs, and then forming the insulating layer having a small thickness by ALD on the electrolyte layer so as to fill any pin holes. Accordingly, a membrane fuel cell may be obtained at a relatively low manufacturing cost.

The ALD is performed at a pressure ranging from about 1×10⁻³ to about 1×10¹ Torr and a temperature ranging from about 100° to about 500° C. If the pressure and the temperature are within these ranges, the insulating layer may densely fill any pin holes formed in the electrolyte layer while also being formed as a conformal layer to thus prevent short circuits from occurring when the electrolyte layer is used in a fuel cell.

According to an embodiment of the invention, a method of manufacturing a solid oxide fuel cell comprises forming a first electrode; forming a solid oxide electrolyte layer on the first electrode; forming an insulating layer as a conformal layer on the solid oxide electrolyte layer, wherein the insulating layer includes nano-grains having an average crystal grain size of 30 nm or less; and forming a second electrode on the insulating layer.

According to one embodiment of the manufacturing method of the invention, the solid oxide fuel cell may include the first electrode, the solid oxide electrolyte layer, the insulating layer and the second electrode, which are sequentially stacked. That is, the insulating layer is formed on only a single surface of the solid oxide electrolyte layer.

According to another embodiment of the invention, a method of manufacturing a solid oxide fuel cell includes forming a solid oxide electrolyte layer; forming an insulating layer as a conformal layer on a single layer or two opposing layers of the solid oxide electrolyte layer, wherein the insulating layer includes nano-grains having an average crystal grain size of 30 nm or less; and forming a first electrode and a second electrode so that the solid oxide electrolyte layer on which the insulating layer is formed may be disposed between the first electrode and the second electrode.

In the solid oxide fuel cell manufactured by the method according to the invention, the first electrode, the solid oxide electrolyte layer, the insulating layer and the second electrode may be sequentially stacked, or alternatively, the first electrode, the insulating layer, the solid oxide electrolyte layer, the insulating layer and the second electrode may be sequentially stacked. That is, the insulating layer may be formed on a single surface or on two opposing surfaces of the solid oxide electrolyte layer.

In the solid oxide fuel cell manufactured by the method of the invention, the forming of the solid oxide electrolyte layer may include preparing a substrate, forming the first electrode on the substrate and then forming the solid oxide electrolyte layer on the first electrode; and preparing a substrate, forming the solid oxide electrolyte layer on the substrate and removing the substrate. The substrate may be a silicon substrate, a manganese oxide substrate, an alumina substrate, or the like.

In the two manufacturing methods of forming a solid oxide fuel cell, the first electrode and the second electrode may be an anode and a cathode, respectively, or vice versa.

The first electrode, the second electrode and the solid oxide electrolyte layer may be each, independently, formed by using sputtering, CVD, PVD, ALD, plating (electroplating or electroless plating), PLD, molecular-beam epitaxy, vacuum deposition, or the like.

A catalyst layer may be further formed on at least one of the first electrode and the second electrode. The catalyst of the catalyst layer may have a nano-particle size. The catalyst layer may be formed by using sputtering, CVD, PVD, ALD, plating (electroplating and electroless plating), PLD, molecular-beam epitaxy, vacuum deposition, or the like.

The catalyst may be at least one metal catalyst or alloy catalyst, or at least two metal catalysts or alloy catalysts selected from the group consisting of platinum (Pt), gold (Au), silver (Ag), ruthenium (Ru), nickel (Ni), palladium (Pd), cobalt (Co), titanium (Ti) and vanadium (V). The catalyst may include at least one oxide catalyst selected from La₁₋ₓSrₓMnO₃ (0<x<1). La₁₋ₓSrₓCoO₃ (0<x<1) and La₁₋ₓSrₓCo_{y}Fe_{1-y}O₃ (0<x<1, 0<y<1). Moreover, the catalyst may include at least one member selected from the group consisting of Pt, Pt—Ru, Pt—Co, Pt—Fe, Pt—Ni, Pt—Ti and Pt—V.

Hereinafter, one or more embodiments of the present invention will be described in detail with reference to the following examples. However, these examples are not intended to limit the purpose and scope of the one or more embodiments of the invention.

### EXAMPLE 1

1) A porous cathode aluminum oxide (AAO) disk having a diameter of 25 mm, a thickness of 100 μm and a pore diameter of 80 nm was used as a substrate for a membrane cell.

2) An anode having a thickness of 400 nm was formed by depositing Pd on the substrate by using a sputtering method with a high-purity Pd target under conditions including a power of 200 W, a distance between the target and the substrate of 80 mm, a deposition time of 25 minutes and an air pressure of 5 mTorr.

3) Then, a BaZr_{0.8}Y_{0.2}O_{3-d} layer as an electrolyte layer having a thickness of 1200 nm was formed on the anode by PLD with a BaZr_{0.8}Y_{0.2}O_{3-d} target. In this case, deposition conditions included a temperature of 600° C., a O₂ pressure of 30 mTorr, a laser power of 200 mJ, a laser frequency of 5 Hz, a deposition time of 160 minutes (about 48000 pulses) and a distance between the target and a substrate (T-S) of 75 mm.

4) An Al₂O₃ layer as an insulating layer having a thickness of about 5 nm (50 cycles) was formed on the electrolyte layer by using ADL under conditions including a pressure of 10⁻² Torr and a temperature of 200° C. In this case, tri-methyl aluminum was used as a precursor, and water was used as a reactant.

5) A cathode having a thickness of about 200 nm was formed by depositing Pt on the insulating layer by sputtering with a high-purity Pt target. Deposition conditions included a power of 200 W, a distance between the target and a substrate of 80 mm, a deposition time of 8 minutes and an air pressure of 50 mTorr. As a result, a membrane Pd/BaZr_{0.8}Y_{0.2}O_{3-d}/Al₂O₃/Pt fuel cell including a cathode having an area of 0.01 cm² was manufactured.

### EXAMPLE 2

A membrane fuel cell was manufactured in the same manner as in Example 1 except that an area of a cathode was 0.04 cm².

### EXAMPLE 3

A membrane fuel cell was manufactured in the same manner as in Example 1 except that the area of the cathode was 0.09 cm².

### COMPARATIVE EXAMPLE 1

A membrane Pd/BaZr_{0.8}Y_{0.2}O_{3-d}/Pt fuel cell including a cathode having an area of 0.01 cm² was manufactured in the same manner as in Example 1 except that an insulating layer was not formed on an electrolyte layer, but a cathode was formed directly on the electrolyte layer.

### COMPARATIVE EXAMPLE 2

A membrane fuel cell was manufactured in the same manner as in Comparative Example 1 except that the area of the cathode was 0.04 cm².

### COMPARATIVE EXAMPLE 3

A membrane fuel cell was manufactured in the same manner as in Comparative Example 1 except that the area of the cathode was 0.09 cm².

Determination of Whether Short Circuits Occur

Whether short circuits occur in a fuel cell was evaluated with reference to data measured according to an electrochemical impedance spectroscopy (EIS) test. Equipment used in this evaluation was 1260A and 1287A available from Solartron.

In detail, AC impedances of the membrane fuel cells manufactured in Examples 1 through 3 and Comparative Examples 1 through 3 were measured along their thickness directions. In this case, the AC impedances were measured at a frequency ranging from about 0.1 to about 1×10⁶ Hz and amplitude of 10 mV, wherein a frequency sweep was performed at an open circuit voltage. From the measuring results of the impedances, when only resistance components were apparent, it was determined that short circuits occurred. When the frequency sweep was performed from a low frequency region towards a high frequency region, if membrane resistance could be measured while impedance value was increased along an imaginary axis, that is, if resistance components and capacitor components were simultaneously apparent, it was determined short circuits did not occur.

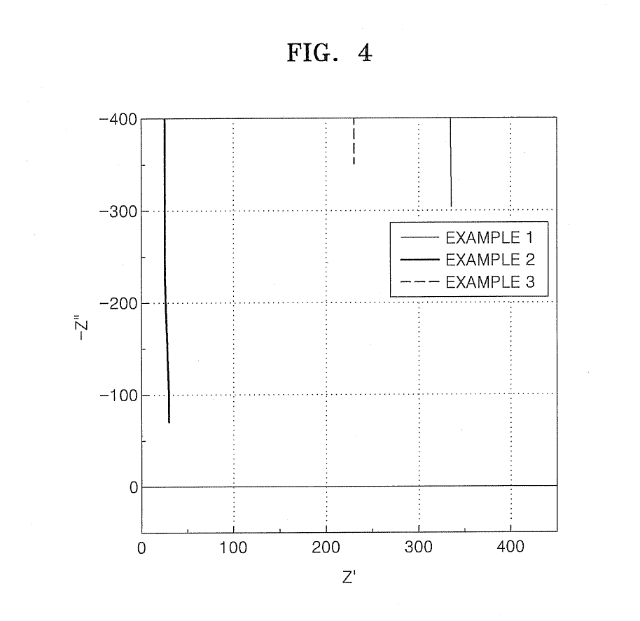

Referring to FIG. 4, with regard to a membrane fuel cell including an insulating layer disposed between an electrolyte and a cathode according to an embodiment of the invention, in Example 3, in which the area of the cathode was 0.09 cm² as well as in Example 1 in which the area of the cathode was 0.01 cm², and Example 2, in which the area of the cathode was 0.04 cm², membrane resistance could be measured while impedance value was increased along an imaginary axis (−Z″), short circuits did not always occur.

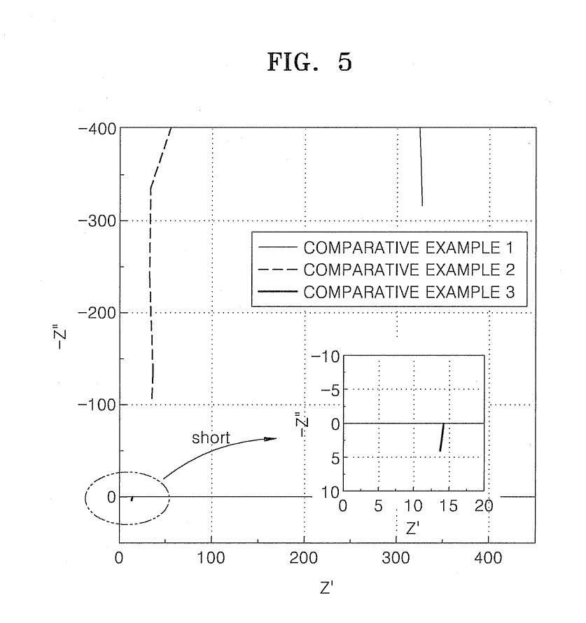

Referring to FIG. 5, with regard to a membrane fuel cell without an insulating layer according to the Comparative Examples, in Comparative Example 1, in which the area of the cathode was 0.01 cm², and Comparative Example 2, in which the area of the cathode was 0.04 cm², short circuits did not occur. However, in Comparative Example 3, in which the area of the cathode was 0.09 cm², short circuits occurred.

As described above, according to the one or more of the above embodiments of the invention, even if pin holes are formed when an electrolyte layer is thinned, an insulating layer formed as a conformal layer on the electrolyte layer so as to fill any pin holes, prevents short circuits from occurring. Accordingly, a fuel cell including a solid oxide electrolyte membrane including the electrolyte layer may be driven at a low temperature while maintaining at least the same performance characteristics as that of a typical fuel cell.

It should be understood that the exemplary embodiments described herein should be considered in a descriptive sense only and not for purposes of limitation. Descriptions of features or aspects within each embodiment should typically be considered as available for other similar features or aspects in other embodiments.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A solid oxide electrolyte membrane comprising:
a solid oxide electrolyte layer; and
an insulating layer formed as a conformal layer on a single surface or on two opposing surfaces of the solid oxide electrolyte layer and comprising nano-grains having an average crystal grain size of 30 nm or less.

2. The solid oxide electrolyte membrane of claim 1, wherein the solid oxide electrolyte layer comprises at least one member selected from the group consisting of an oxygen ion conductive solid oxide, a hydrogen ion conductive solid oxide, and an oxygen ion and hydrogen ion mixed conductive solid oxide.

3. The solid oxide electrolyte membrane of claim 2, wherein the oxygen ion conductive solid oxide comprises at least one member selected from the group consisting of zirconia doped with yttrium (Y) or scandium (Sc); ceria doped with at least one of gadolinium, samarium, lanthanium, ytterbium and neodymium; and lanthanum gallate doped with strontium or magnesium.

4. The solid oxide electrolyte membrane of claim 2, wherein the hydrogen ion conductive solid oxide comprises at least one member selected from a parent perovskite group consisting of barium zirconate, barium cerate, strontium cerate and strontium zirconate, which are each doped with a trivalent element.

5. The solid oxide electrolyte membrane of claim 2, wherein the oxygen ion and hydrogen ion mixed conductive solid oxide comprises at least one member selected from the group consisting of BaZrO₃, BaCeO₃, SrZrO₃ and SrCeO₃ which is doped with a trivalent element; and Ba₂In₂O₅ doped with at least one positive ion of at least one of vanadium, niobium, tantalum, molybdenum and tungsten.

6. The solid oxide electrolyte membrane of claim 1, wherein the insulating layer comprises at least one member selected from the group consisting of an oxygen ion conductive solid oxide, a hydrogen ion conductive solid oxygen and an oxygen ion and hydrogen ion mixed conductive solid oxide.

7. The solid oxide electrolyte membrane of claim 6, wherein the oxygen ion conductive solid comprises at least one member selected from the group consisting of zirconia that may optionally be doped with yttrium (Y) or scandium (Sc); ceria that may optionally be doped with at least one of gadolinium, samarium, lanthanium, ytterbium and neodymium; and lanthanum gallate that may optionally be doped with strontium or magnesium.

8. The solid oxide electrolyte membrane of claim 6, wherein the hydrogen ion conductive solid oxide comprises at least one member selected from a parent perovskite group consisting of barium zirconate, barium cerate, strontium cerate and strontium zirconate, each of which may optionally be doped with a trivalent element.

9. The solid oxide electrolyte membrane of claim 6, wherein the oxygen ion and hydrogen ion mixed conductive solid oxide comprises at least one member selected from the group consisting of BaZrO₃, BaCeO₃, SrZrO₃ or SrCeO₃ which may optionally be doped with a trivalent element; and Ba₂In₂O₅ that may optionally be doped with at least one positive ion of vanadium, niobium, tantalum, molybdenum and tungsten.

10. The solid oxide electrolyte membrane of claim 1, wherein the insulating layer comprises at least one member selected from the group consisting of aluminum oxide, aluminosilicates and titanium oxide.

11. A method of manufacturing a solid oxide electrolyte membrane comprising forming an insulating layer as a conformal layer on a solid oxide electrolyte layer, wherein the insulating layer comprises nano-grains having an average crystal grain size of 30 nm or less.

12. The method of claim 11, wherein the insulating layer is formed by chemical vapor deposition (CVD) method, a plating method, a molecular-beam epitaxy method, a vacuum deposition method or a combination thereof.

13. The method of claim 11, wherein he insulating layer is formed by a CVD method.

14. The method of claim 11, wherein the insulating layer is formed by an atomic layer deposition (ALD) method.

15. A fuel cell comprising the solid oxide electrolyte membrane of claim 1.
